(19) United States
(12) Patent Application Publication
(10) Pub. No.: US 2015/0160275 A1
(43) Pub. Date: Jun. 11, 2015

(54) SYSTEM AND METHOD FOR MONITORING POWER CONSUMPTION OF AN LED LAMP

(71) Applicant: Progress Rail Services Corporation, Albertville, AL (US)

(72) Inventor: Todd C. Goergen, Blue Springs, MO (US)

(73) Assignee: Progress Rail Services Corporation, Albertville, AL (US)

(21) Appl. No.: 14/103,039

(22) Filed: Dec. 11, 2013

(51) Int. Cl. G01R 21/06; G01R 31/26; G01R 31/44

(52) U.S. Cl. CPC G01R 21/06; G01R 31/44; G01R 31/2635

(57) ABSTRACT

A system is provided for monitoring power consumption of a light emitting diode (LED) lamp. The system includes a first sensor, a second sensor and a processor. The first sensor is associated with a voltage level. The second sensor is associated with a current level light emitting diode and a monitoring module. Further, the processor is configured to receive a voltage signal from the first sensor and a current level signal from the second sensor and determine a power level consumption of the LED lamp.

### TECHNICAL FIELD

The present disclosure relates generally to a system and method for monitoring power consumption of a light emitting diode (LED) lamp and, more particularly, to a system and method for monitoring power consumption of an LED lamp for railway crossing applications.

### BACKGROUND

Railroad gate systems may consist of a plurality of railway gate lamps such as crossing gate and warning lamps. Some railroads use incandescent bulbs in railway lamps. Failure of such incandescent bulbs may be easily detected since the incandescent bulbs cease to produce light in a failure. In a situation in which the incandescent lights are replaced with light emitting diodes, failure detection cannot be accomplished as easily by monitoring a decrease of light emission. The LED lamps have a tendency to slowly dim and lose intensity over time. Hence, there is a need to monitor when there is a failure in the LED lamps caused by light intensity dropping below a threshold value.

### SUMMARY OF THE DISCLOSURE

In one aspect of the present disclosure, a system for monitoring power consumption of a light emitting diode (LED) lamp is disclosed. The system includes a first sensor associated with a voltage level and a second sensor associated with a current level. Further, a processor is configured to receive a voltage signal from the first sensor and the current level signal from the second sensor and responsively determine a power level consumption of the LED lamp.

In another aspect of the present disclosure, a method for monitoring power level consumption for an LED lamp is provided. The method includes receiving a first signal associated with a voltage level. The method also includes receiving a second signal associated with a current level. Further, the method provides for determining a power level consumption of the LED lamp as a function of the first and second signals.

Other features and aspects of this disclosure will be apparent from the following description and the accompanying drawings.

### BRIEF DESCRIPTION OF THE DRAWINGS

FIG. 1 is a diagrammatic view of a front end of an exemplary locomotive, according to one embodiment of the present disclosure;

FIG. 2 is a block diagram of a monitoring system for a light emitting diode present on the machine;

FIG. 3 is a flowchart for monitoring operational health of the light emitting diode;

FIG. 4 illustrates a diagrammatic view of a front view of an exemplary railway gate system, according to one embodiment of the present disclosure;

FIG. 5 illustrates in block diagram form a system for monitoring power level consumption of an LED lamp in accordance with another embodiment of the present disclosure; and

FIG. 6 illustrates in flowchart form a method for monitoring power consumption of an LED lamp in accordance with one embodiment of the present disclosure.

### DETAILED DESCRIPTION

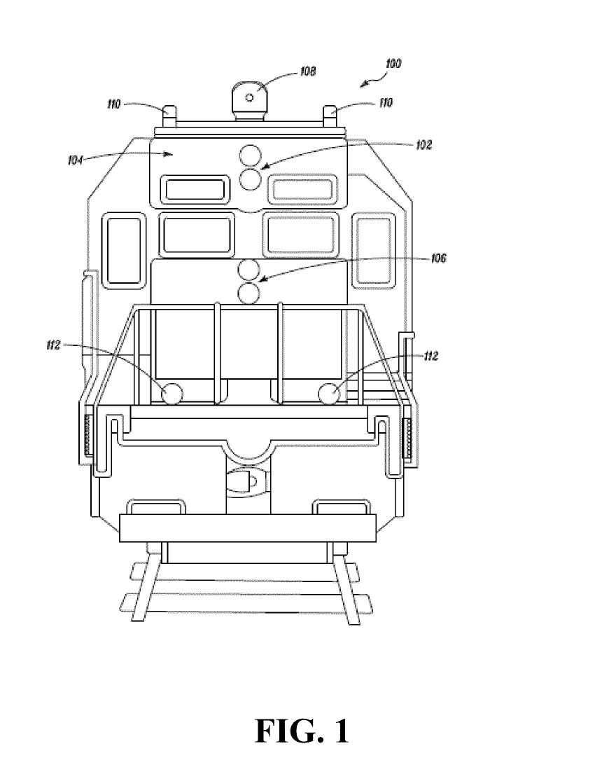

FIG. 1 is a diagrammatic view of a front end of an exemplary locomotive 100, according to one embodiment of the present disclosure. More particularly, FIG. 1 depicts the positioning of a headlight 102 and various alerting lights installed on the front end of the locomotive 100. As shown in FIG. 1, the headlights 102 may be mounted near a top portion of a crew cab 104 or below the crew cab 104 on a nose of the locomotive 100. The headlight 102 is typically designed to illuminate a track area directly in front of the locomotive 100. This may allow an operator to view a specific distance ahead of the locomotive 100 in order to see signals and otherwise operate the locomotive 100 is a safe manner.

The alerting lights may include oscillating lights 106, beacon lights 108, strobe lights 110, ditch lights 112, and the like. For example, the oscillating light 106 may be mounted on the front end of the locomotive 100 and aimed down a track centerline. The beacon light 108 may be mounted on the top of the locomotive 100, as far front as possible, on the centerline of the locomotive 100. The strobe lights 110 may be positioned in pairs, one on each side, on a roof or on a lower front end of the locomotive 100. The ditch light 112 may be designed to illuminate a part of the track right-of-way lying outside an area normally illuminated by the headlight 102. The alerting lights are used to supply visual signals to the operator. These visual signals are formed by a light source which may differ in number, intensity, location on the locomotive, beam width, and focus angle. Such alert lights may be applied or used in a railway gate system.

A person of ordinary skill in the art will appreciate that the LED 202 operates differently from incandescent lights. For example, the incandescent light is considered failed or defective when the incandescent light no longer gives off light. However, the LED 202 does not fail in the similar manner. With usage over time, an intensity of the LED 202 may drop below a required pre-determined candela level specified for the locomotive 100.

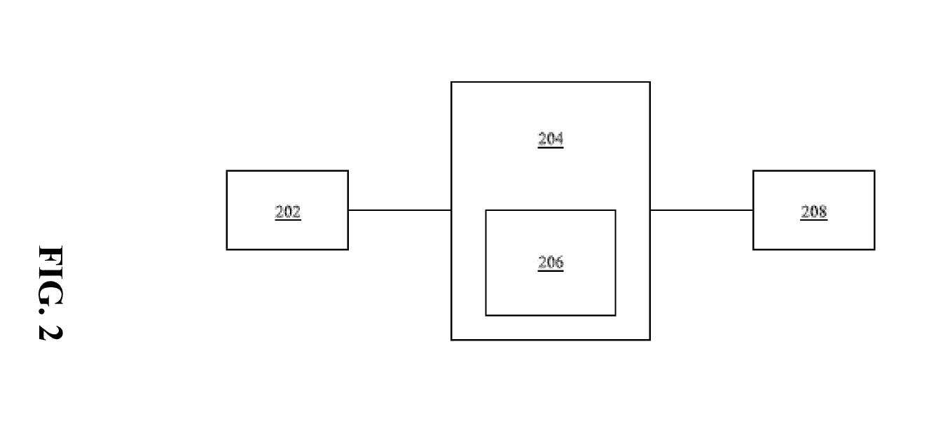

Referring to FIG. 2, the present disclosure relates to a monitoring module 204 for monitoring an operational health of the LED 202. The monitoring module 204 is configured to receive one or more signals indicative of power consumption of the LED 202. Further, the monitoring module 204 is configured to determine a condition of the LED 202 based, at least in part, on the received signals. The condition of the LED 202 may include a weak output state or failure of the LED 202, as the case may be.

It should be noted that in the present disclosure, the intensity of the LED 202 may be determined based on the power consumption of the LED 202. This metric may provide a substantially accurate estimate of the intensity of the LED 202 as against the usage of parameters like voltage, current, and the like. Also, it should be understood that the disclosure described herein may apply to any LED based lighting system making use of a plurality of the LEDs 202 arranged in a series configuration, parallel configuration or any other electrical configuration making use of either a single LED 202 or multiple LEDs 202.

The monitoring module 204 may be communicably coupled either directly or indirectly to the LED 202. In one embodiment, the monitoring module 204 may be coupled to an electronic controller present within the locomotive 100, which in turn is coupled to the LED 202. The monitoring module 204 is configured to receive the one or more signals indicative of the power consumption of the LED 202. In one embodiment, the one or more signals may include a voltage signal indicative of the voltage across the LED 202; and a current signal indicative of the current flowing through the LED 202. The power consumption of the LED 202 may be estimated based on these signals.

These signals may be received at a pre-determined time, in accordance with one embodiment of the present disclosure. One of ordinary skill in the art will appreciate that these signals may be measured using techniques known in the art. For example, a voltage sensing element and/or current sensing element, such as, a differential amplifier or other known circuitry may be used to generate signals indicative of the voltage and current associated with the LED 202.

Further, the monitoring module 204 may include a comparison module 206. The comparison module 206 may be configured to compare the power consumption of the LED 202 with a pre-determined threshold level. This threshold level may specify a given candela level which must be met by LED 202 installed on the locomotive 100. For example, as per regulations, the pre-determined threshold for the LEDs 202 used on the locomotive 100 for road service is approximately 200,000 candela. Moreover, the pre-determined threshold for the LEDs 202 used on the locomotive 100 for yard service is approximately 60,000 candela.

It should be noted that the sensed feedback at the pre-determined time of the power consumption of the LED 202, hereinafter referred to as instantaneous power consumption, may be used to determine the operational health of the LED 202 at the time the sensed feedback is measured. In one embodiment, based on the instantaneous power consumption of the LED 202, the monitoring module 204 may predict an occurrence of the failure of the LED 202. The prediction may provide an estimation of remaining life in a particular LED 202, or collective life remaining for the set or subset of the LEDs 202. Hence, in a situation wherein the intensity of the LED 202 is relatively near to the pre-determined threshold, thereby tending to failure, the monitoring module 204 may predict when the LED 202 will fail.

The monitoring module 204 may also be coupled to a display module 208. The display module 208 may include at least one of an indicator light, a display gauge, and a monitor. In one embodiment, the display module 208 may be present in the crew cab 104 of the locomotive 100. The display module 208 may be configured to notify the operator in case of failure and/or weak output of the LED 202. The notification may be in the form of any suitable visual and/or auditory feedback, indicative of the failure of the single LED 202 or the multiple LEDs 202. Moreover, in one embodiment, the notification may be a warning to the operator based on the predicted failure of the LED 202.

It should be noted that the connections shown in FIG. 2 are merely on an exemplary basis. Other components not shown herein may also be part of the system. Moreover, in one embodiment, the monitoring module 204 may be invoked manually by the operator via suitable controls present in the crew cab 104. Alternatively, the monitoring module 204 may be automatically invoked after a pre-determined time period.

Further, the monitoring module 204 may embody a single microprocessor or multiple microprocessors that include a means for receiving the one or more signals indicative of the power consumption of the LED 202. Numerous commercially available microprocessors may be configured to perform the functions of the monitoring module 204. It should be appreciated that the monitoring module 204 may readily embody a general machine microprocessor capable of controlling other functions. A person of ordinary skill in the art will appreciate that the monitoring module 204 may additionally include other components and may also perform other functionality not described herein.

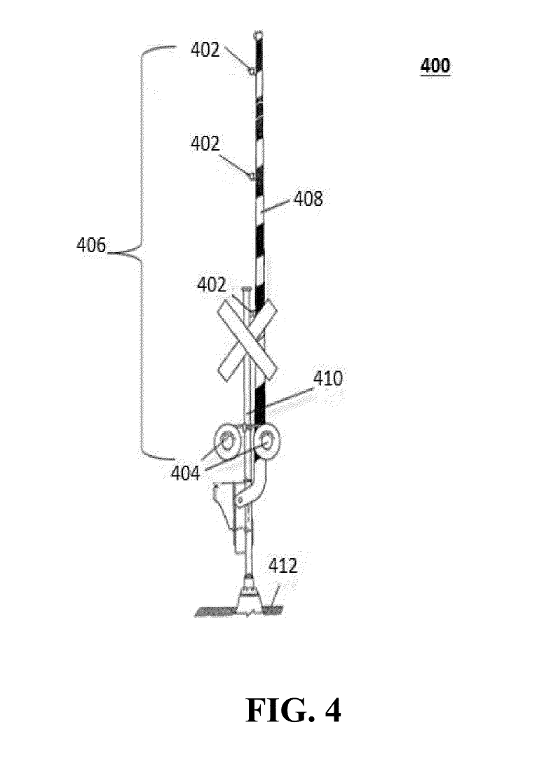

FIG. 4 illustrates an example of railway gate system 400 that includes railway gate lamps 406. Such railway gate lamps 406 are configured as LED lamps and may include crossing lamps 402 and warning lamps 404. Such LED lamps may also be applied in railway gate system 400 without crossing gate arms 408. FIG. 4 also depicts the positioning of a plurality of crossing gates lamps 402 that are positioned distally along the crossing gate arm 408 of the railway gate system 400. Additionally, warning gate lamps 404 may be positioned on a post 410 that is located in a horizontal position 412 of the railway gate system 400.

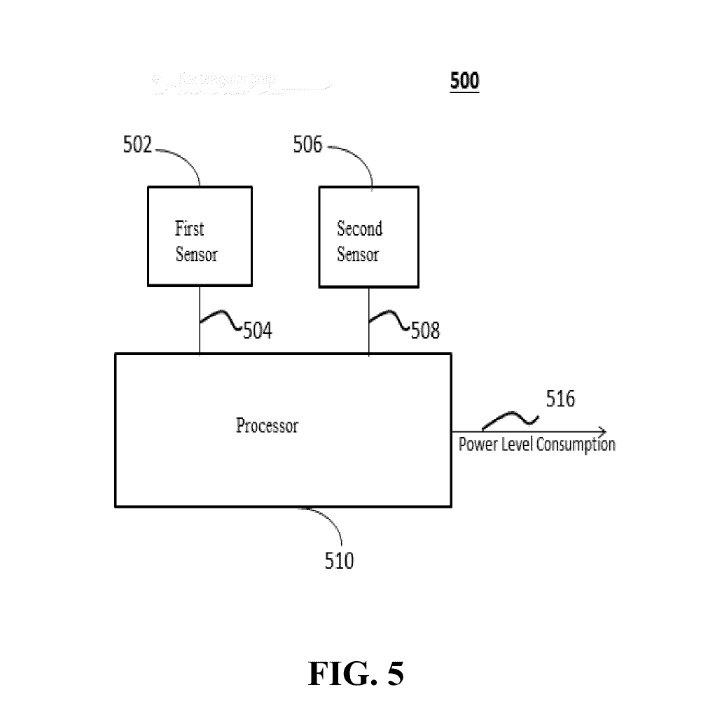

FIG. 5 illustrates in block diagram form a system 500 for monitoring power level consumption of an LED lamp in accordance with another embodiment of the present disclosure. FIG. 5 illustrates a processor 510 for monitoring a power level consumption 516 of an LED lamp. The processor 510 is configured to receive a voltage signal 504 from a first sensor 502 and a current level signal 508 from a second sensor 506 and responsively determine a power level consumption 516 of the LED lamp.

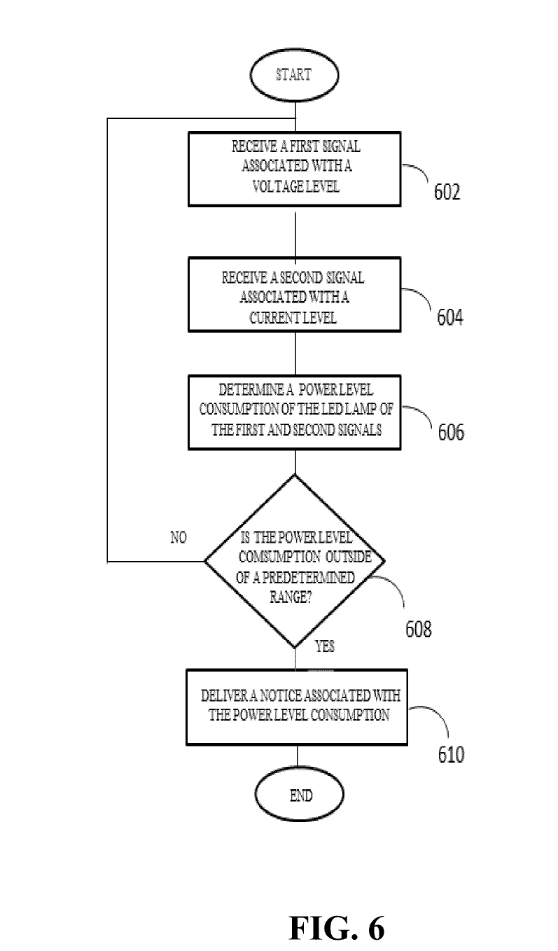

The processor 510 may be configured to determine the power level consumption 516 having a value outside a predetermined range. The processor 510 may include any devices capable of receiving voltage signals 504 from the first sensor 502 and current level signals 508 from the second sensor 506. In certain embodiments, the processor 510 may be embodied by a computer or other device that may include a controller, a memory, and a storage (not shown). The memory may include one or more programs loaded from the storage or elsewhere that, when executed by the controller, enable the processor 510 to perform various procedures, operations, or processes consistent with disclosed embodiments, including the processes described in FIG. 6 below. The power level consumption may have operating values within a range wherein the LED lamp is within normal operating mode. Such a range may define a predetermined level for normal operation. The processor 510 may be configured to determine when the power level consumption 516 has a value outside, below, and above such predetermined level. Thus, processor 510 may deliver a notice associated with the power level consumption 516 relative to the predetermined level.

The second sensor 506 may be configured as a Hall Effect current sensor. Also, the LED lamp may be a railway gate lamp 406. As used herein, the railway gate lamp 406 can be, for example, a crossing gate lamp and/or a warning lamp.

### INDUSTRIAL APPLICABILITY

The locomotives 100 used in road service, make use of standard dual, sealed beam, incandescent lights which are mounted together, either horizontally or vertically, on the front of the locomotive 100. However, the use of LEDs 202 is now beginning to replace the incandescent lights on the locomotive 100. Regulations require that the intensity of a headlight beam of each of the locomotives 100 used in road service be at least approximately 200,000 candela. Also, the intensity for the locomotives 100 used in yard service is desired to be approximately 60,000 candela. These intensity levels may serve as the pre-determined threshold parameter to be met during testing of the LED 202.

In the present disclosure, the monitoring module 204 may determine the intensity of the LED 202 based on the power consumption of the LED 202. The power consumption and/or the instantaneous power consumption of the LED 202 may provide relatively accurate indication of the operational health of the LED 202.

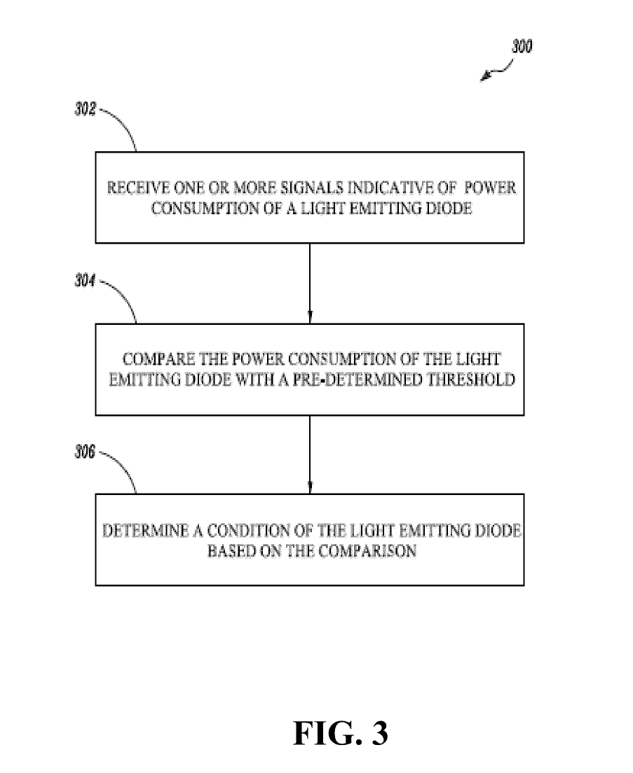

A method 300 for monitoring the operational health of the LED 202 will be described in connection with FIG. 3.

At a first step 302, the one or more signals indicative of the power consumption and/or the instantaneous power consumption of the LED 202 are received. These signals may include the voltage and current signals associated with the LED 202. The signals may be measured at the pre-determined time. Thereafter at a second step 304, the comparison module may compare the received signals with the pre-determined threshold.

At a third step 306, the monitoring module 204 may determine the condition of the LED 202 based on the comparison. In one embodiment, if the intensity estimated from the received signals is nearing the pre-determined threshold, then the monitoring module 204 may determine that the LED 202 is in a weak output state. If the intensity of the LED 202 is well below the pre-determined threshold then the monitoring module 204 may determine that the LED 202 has failed. In one embodiment, if the intensity estimated from the received signals is higher than the pre-determined threshold or close to failure, then the monitoring module 204 may predict when the LED 202 may fail. Moreover, on failure of the LED 202, the display module 208 may notify the operator of the failure using suitable feedback. A person of ordinary skill in the art will appreciate that the monitoring module 204 may be utilized on an application using the LED 202. Although the disclosure described herein is in connection with the headlight 102 and/or the alerting lights on the locomotive 100, this application does not limit the scope of the disclosure.

FIG. 6 illustrates an embodiment of a flow diagram of a method for monitoring the power level consumption of an LED lamp. Examples of such an LED lamp may include crossing gate lamps 402 and warning gate lamps 404. At a first control block 602, a first signal associated with a voltage level is received by a processor 510. At a second control block 604, a second signal associated with a current level is received by the processor 510. At a third control block 606, the processor 510 determines a power level consumption 516 for the LED lamp based on the first and second signals. At a first decision block 608, the processor 510 determines whether the power level consumption 516 is outside a predetermined range. The power level consumption 516 may have operating values within a range wherein the LED lamp is operating in a normal mode. Such a range may define a predetermined level for normal operation. The processor 510 may be configured to determine when the power level consumption 516 has a value outside, below, or above such predetermined level. At a fourth control block 610, the processor 510 delivers a notice associated with the power level consumption 516 if the consumption is determined to be outside the predermined range. However, if the consumption is not outside the predetermined range, control returns to the first control box 602.

Although the embodiments of this disclosure as described herein may be incorporated without departing from the scope of the following claims, it will be apparent to those skilled in the art that various modifications and variations can be made. Other embodiments will be apparent to those skilled in the art from consideration of the specification and practice of the disclosure. It is intended that the specification and examples be considered as exemplary only, with a true scope being indicated by the following claims and their equivalents.

What is claimed is:

1. A system for monitoring power consumption of an light emitting diode (LED) lamp comprising:
a first sensor associated with a voltage level;
a second sensor associated with a current level; and
a processor configured to receive a voltage signal from the first sensor and a current level signal from the second sensor and responsively determine a power level consumption of the LED lamp.

2. The system of claim 1 wherein the processor is configured to determine a power level consumption having a value outside a predetermined range.

3. The system of claim 2 wherein the processor is configured to determine a power level consumption having a value below a predetermined level.

4. The system of claim 2 wherein the processor is configured to determine a power level consumption having a value above a predetermined level.

5. The system of claim 2 wherein the processor is configured to deliver a notice associated with the power level consumption.

6. The system of claim 1 wherein the second sensor is a Hall Effect current sensor.

7. The system of claim 1 wherein the LED lamp is a railway lamp.

8. The system of claim 7 wherein the railway lamp is a crossing gate lamp.

9. The system of claim 7 wherein the railway lamp is a warning lamp.

10. A method for monitoring power consumption of an LED lamp comprising:
receiving a first signal associated with a voltage level;
receiving a second signal associated with a current level; and
determining a power level consumption of the LED lamp as a function of the first and second signals.

11. A method as set forth in claim 10, wherein determining a power level consumption includes the step of determining a power level consumption having a value outside a predetermined range.

12. A method as set forth in claim 11, including the step of delivering a notice associated with the power level consumption.
